(19) United States
(12) Patent Application Publication
(10) Pub. No.: US 2006/0022316 A1
(43) Pub. Date: Feb. 2, 2006

(54) Semiconductor package with flip chip on leadless leadframe

(75) Inventors: Yao-Ting Huang, Kaohsiung (TW); Chih-Huang Chang, Yongkang City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Advanced Semiconductor Engineering, Inc.

(21) Appl. No.: 11/135,678

(22) Filed: May 24, 2005

(30) Foreign Application Priority Data
Jun. 24, 2004 (TW) 93118311

(51) Int. Cl. H01L 23/495

(52) U.S. Cl. 257/676; 257/778

(57) ABSTRACT

A semiconductor package with flip chip on leadless leadframe includes a leadless leadframe, a ring-shaped tape, a flip chip and an underfilling material. The leadframe has a plurality of inner leads. Connecting regions are defined on the upper surfaces of the inner leads. The ring-shaped tape is disposed on the upper surfaces of the inner leads and has an opening leaving the connecting regions exposed. The flip chip is bonded inside the opening of the ring-shaped tape and has a plurality of bumps connected to the connecting regions of the inner leads. The underfilling material is confined by the ring-shaped tape to be inside the opening for leaving the bumps of the flip chip exposed.

This application claims the benefit of Taiwan application Serial No. 9311831 1, filed Jun. 24, 2004, the subject matter of which is incorporated herein by reference.

### BACKGROUND OF THE INVENTION

1. Field of the Invention

The invention relates in general to a semiconductor package with flip chip on leadframe, and more particularly to a semiconductor package with flip chip on leadless leadframe.

2. Description of the Related Art

Along with the development in semiconductor technology, the packaging of flip chip is getting more diversified. A flip chip on leadframe is achieved by connecting a plurality of bumps disposed on the active surface of a flip chip onto a plurality of leads of a leadframe without using bonding wire for electrical connection. According to Taiwanese Patent Publication No. 463342, a flip chip with quad flat leadless (QFL) leadframe includes a plurality of leads, a chip using a plurality of bumps to be bonded on the leads, and a packaging material for sealing the leads and the chip is disclosed. A solder mask layer, which is formed on the upper surface of the leads, includes an aperture corresponding to the connecting position of the bumps. However, the matching and manufacturing for the solder mask layer to be formed on the upper surface of the leads is more difficult.

Referring to FIG. 1, another conventional semiconductor package, which includes a leadframe 10, is provided. The leadframe 10 includes a plurality of inner leads 11. A solder mask layer 20 is formed on the upper surface of the leads 11 through printing, and fills up the gap between the leads 11. Next, through exposing or developing, an aperture is formed on the solder mask layer 20 corresponding to the leads 11 for exposing the connecting regions 11 a of the leads 11. Then, a plurality of bumps 31 of a flip chip 30 is bonded on the connecting regions 11 a of the leads 11. Lastly, an underfilling material 40 is filled up between the flip chip 30 and the leadframe 10 to protect the flip chip 30. After the solder mask layer 20 is formed on the upper surface of the leads 11, the solder mask layer 20 is filled up between the gaps of the leads 11. Consequently, the solder mask layer 20 is likely to overflow to the lower surface of the leads 11, affecting the upper plate of the semiconductor package. Moreover, to form a solder mask layer 20 on the leadframe 10 needs to go through the manufacturing process of printing, exposing, developing, and making an aperture, adding more to the manufacturing costs.

### SUMMARY OF THE INVENTION

It is therefore a main object of the invention to provide a semiconductor package with flip chip on leadless leadframe. A ring-shaped tape with an opening is disposed on an upper surface of a plurality of inner leads for exposing a plurality of connecting regions of the inner leads. A plurality of bumps of a flip chip are connected to the connecting regions, an underfilling material is formed in the opening of the ring-shaped tape for sealing the bumps of the flip chip. The ring-shaped tape is confined inside the opening by the underfilling material, not only preventing the underfilling material from overflowing, but also controlling the height of the underfilling material.

It is therefore a second object of the invention to provide leadframe assembly of a semiconductor package with flip chip on leadless leadframe. A ring-shaped tape with an opening is disposed on an upper surface of a plurality of inner leads for exposing a plurality of connecting regions of the inner leads. The exposed connecting regions provide bonding for a plurality of bumps a flip chip to replace a solder mask layer according to the prior art which possesses several manufacturing processes including printing, exposure, development, and windowing. When an underfilling material is formed, the underfilling material is confined inside the opening by the ring-shaped tape to prevent the underfilling material from overflowing.

The semiconductor package with flip chip on leadless leadframe according to the invention includes a leadless leadframe, a ring-shaped tape, a flip chip and an underfilling material. The leadframe includes a plurality of inner leads, each of which includes an upper surface and a lower surface. A plurality of connecting regions are defined on the upper surfaces. The ring-shaped tape includes an opening disposed on the upper surface of the inner leads for exposing the connecting regions. The flip chip is disposed on the upper surface of the inner leads and is inside the opening of the ring-shaped tape. The flip chip includes an active surface with a plurality of bumps formed thereon. The bumps are connected to the connecting regions of the inner leads. The underfilling material is confined by the ring-shaped tape to be inside the opening for sealing the bumps.

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIG. 1 (Prior Art) is a sectional view of a conventional semiconductor package with flip chip on leadless leadframe;

FIG. 2 is a sectional view of a semiconductor package with flip chip on leadless leadframe according to the invention;

FIG. 3 is a front view of a leadless leadframe applied in the semiconductor package according to the invention;

FIGS. 4A to 4F are sectional views of a leadless leadframe in the manufacturing method of a semiconductor package with flip chip on leadless leadframe according to the invention; and

FIG. 5 is a front view after a ring-shaped tape is formed on the leadless leadframe according to the invention.

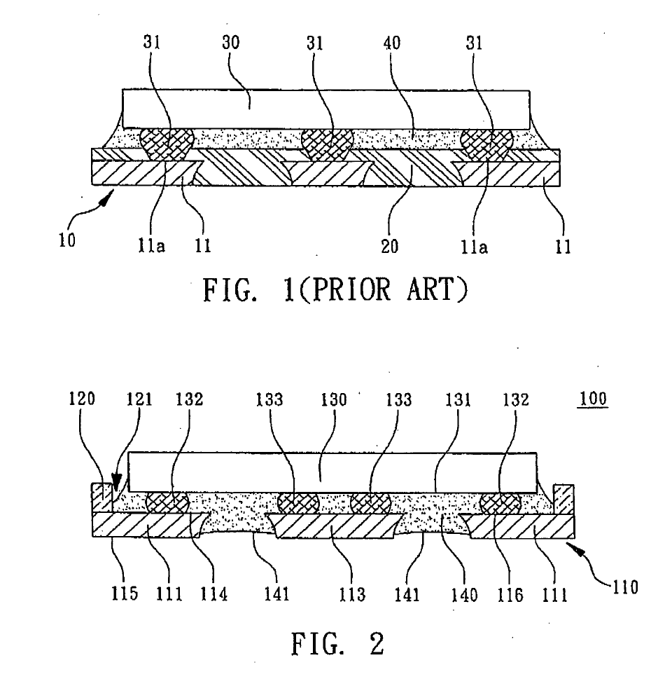

### DETAILED DESCRIPTION OF THE INVENTION

Referring to the accompanying drawings, the invention is exemplified by the embodiment disclosed below.

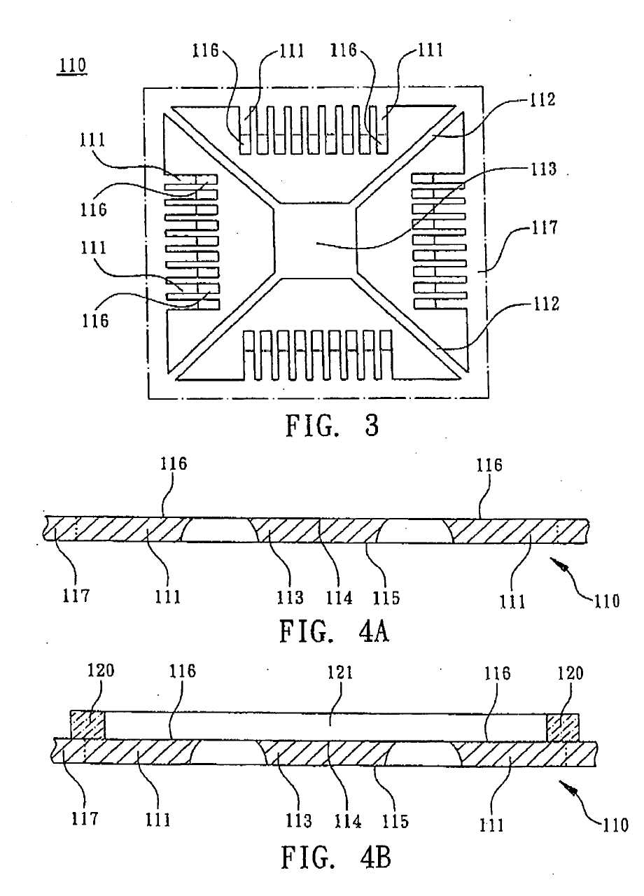

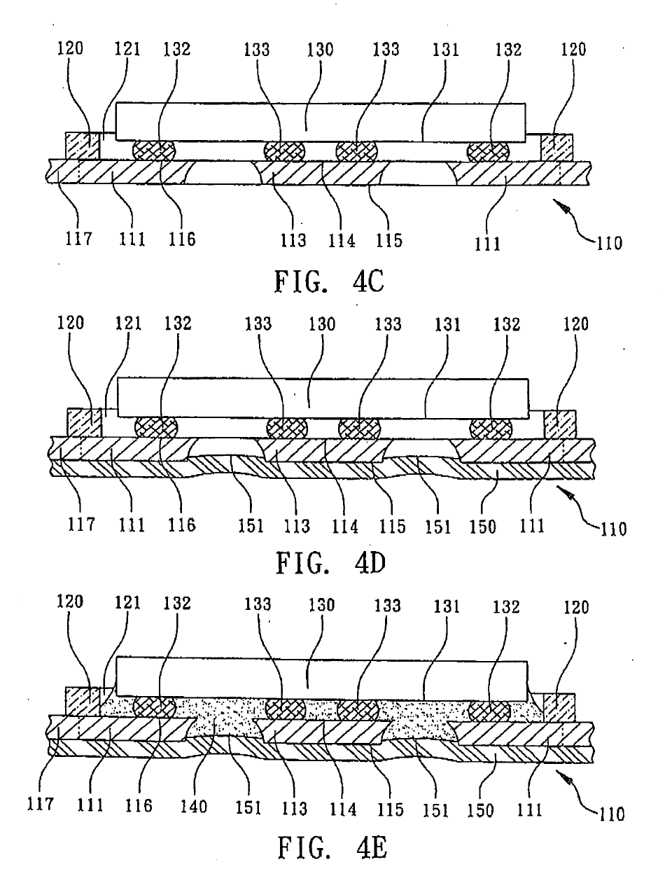

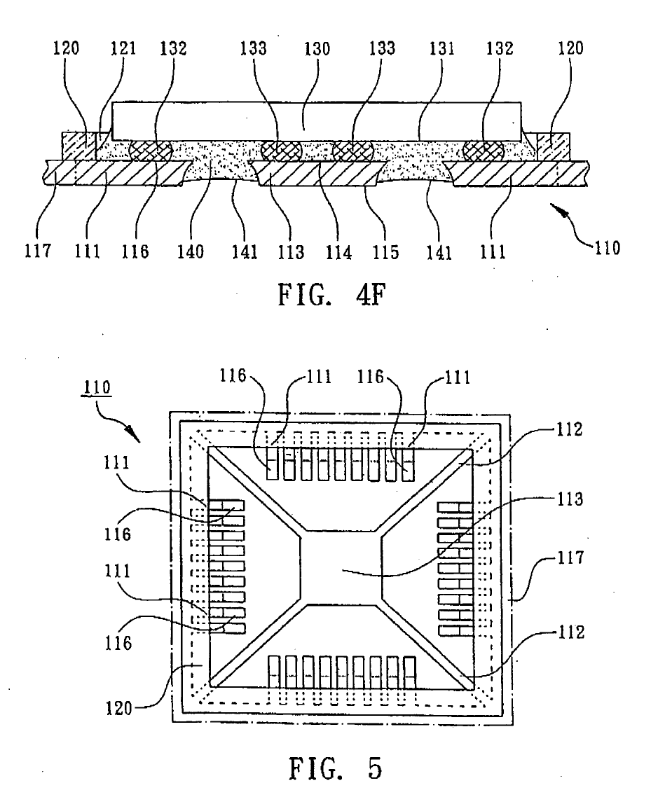

Referring to FIG. 2, a semiconductor package with flip chip on leadless leadframe 100 includes a leadless leadframe 110, a ring-shaped tape 120, a flip chip 130 and an underfilling material 140. A front view of the leadframe 110 is shown in FIG. 3. In the present embodiment, the leadframe 110 includes a plurality of inner leads 111, a plurality of linking sticks 112 and a heat spreader 113. Each of the inner leads 111 includes an upper surface 114 and a lower surface 115. A plurality of connecting regions 116 are defined on the upper surfaces 114. The heat spreader 113 is connected to the linking sticks 112. The ring-shaped tape 120, disposed on the upper surface 114 of the inner leads 111, includes an opening 121 for exposing the connecting regionsll6 as shown in FIG. 5. The material of the ring-shaped tape 120 is polyimide or resin. The flip chip 130 is disposed on the upper surface 114 of the inner leads 111 and is positioned within the opening 121 of the ring-shaped tape 120. The heat spreader 113 is disposed underneath the flip chip 130. The flip chip 130 includes an active surface 131 with a plurality of conductive bumps 132 and at least one heat conductive bumps 133 being formed thereon. The bumps 132 are connected to the connecting region 116 of the inner leads 111. The heat conductive bumps 133 are formed in the central region of the active surface 131 and are bonded onto the heat spreader 113. The underfilling material 140 is confined to be inside the opening 121 of the ring-shaped tape 120 for sealing the bumps 132 and the heat conductive bumps 133. The underfilling material 140 includes an exposed bottom surface 141 positioned between the upper surface 114 and lower surface 115 of the inner leads 111. Furthermore, a film 150 can be pasted onto the lower surface 115 of the inner leads 111 as shown in FIG. 4E.

The ring-shaped tape 120 of the semiconductor package 100 is disposed on the upper surface 114 of the inner leads 111, moreover, the opening 121 of the ring-shaped tape 120 exposes the connecting region 116 of the inner leads 111, so that when the underfilling material 140 is formed within the opening 121 of the ring-shaped tape 120 and seals the bumps 132 of the flip chip 130 and the heat conductive bumps 133, the ring-shaped tape 120 limits the underfilling material 140 to be inside the opening 121, not only preventing the underfilling material 140 from overflowing, but also controlling the height of the underfilling material 140.

The manufacturing method of the semiconductor package 100 is disclosed below.

Firstly, refer to FIG. 3 and FIG. 4A. At first, a leadless leadframe 110 of matrix design of provided. The embodiment is exemplified by a package unit. The leadframe 110 includes a plurality of inner leads 111, a plurality of linking sticks 112 and a heat spreader 113. Each of the inner leads 111 includes an upper surface 114 and a lower surface 115. A plurality of connecting regions 116 are defined on the upper surfaces 114. The inner leads 111 of the leadframe 110 are connected to a plurality of supporting sticks 117. Referring to FIG. 4B and FIG. 5, a ring-shaped tape 121 is formed on the upper surface 114 of the inner leads 111. The ring-shaped tape 120 includes an opening 121 for exposing the connecting regions16. The area surrounded by the supporting sticks 117 is larger than the area of the opening 121 of the ring-shaped tape 120. Preferably, the ring-shaped tape 120 contacts the supporting sticks 117. Further referring to FIG. 4C, a flip chip 130 is bonded on the leadframe 110. The flip chip 130 is disposed on the upper surface 114 of the inner leads 111 and is positioned within the opening 121 of the ring-shaped tape 120. An active surface 131 of the flip chip 130 has a plurality of bumps 132 and at least one heat conductive bumps 133 formed thereon. The bumps 132 are connected to the connecting regions16 of the inner leads 111. The heat conductive bumps 133 are connected to the heat spreader 113. Further referring to FIG. 4D, a film 150 is provided. The film 150 includes an adhering surface 151 for the film 150 to be pasted on the lower surface 115 of the inner leads 111 and the bottom surface of the heat spreader 113, so that the ring-shaped tape 120, the supporting sticks 117 and the film 150 together limit and isolate the flowing range of the underfilling material 140. Due to the tension of the film 150, the adhering surface 151 exposed between the inner leads 111 is positioned between the upper surface of 114 and the lower surface 115 of the inner leads 111. Further referring to FIG. 4E, an underfilling material 140 is formed within the opening 121 of the ring-shaped tape 120. The underfilling material 140 is confined by the ring-shaped tape 120 to be inside the opening 121 for sealing the bumps 131 and the heat conductive bumps 133. Since the adhering surface 151 exposed between the inner leads 111 is positioned between the upper surface 114 and the lower surface 115 of the inner leads 111, the contact surface between the underfilling material 140 and the film 150 is positioned between the upper surface 114 and the lower surface 115 of the inner leads 111. Further referring to FIG. 4F, the film 150 is removed for exposing the lower surface 115 of the inner leads 111, so that the underfilling material 140 has an exposed bottom surface 141, positioned between the upper surface 114 and the lower surface 115 of the inner leads 111. That is, a height difference exists between the exposed bottom surface 141 of the underfilling material 140 and the lower surface 115 of the inner leads 111 for increasing the bonding between the semiconductor package 100 and external circuit board (not shown in the diagram). Next, the supporting sticks 117 are deleted, so that the inner leads 111 are free of short-circuit and that the semiconductor package 100 shown in FIG. 2 is obtained.

Besides, under the spirit of the invention, the step of pasting the film 150 only needs to be performed before the step of forming the underfilling material 140, and does not necessarily be performed after the step of bonding the flip chip 130. That is, the step of pasting the film 150 can be performed either before or after the step of forming the ring-shaped tape 121, so that the leadframe 110, the ring-shaped tape 120 and the film 150 together form a leadframe assembly applicable to a semiconductor package with flip chip on leadless leadframe. Then, the steps of bonding the flip chip 130, forming the underfilling material 140, removing the film 150 and deleting the supporting sticks 117 are performed sequentially to obtain the semiconductor package 100.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A semiconductor package, comprising:
a leadless leadframe having a plurality of inner leads, wherein each inner lead has an upper surface and a lower surface, and a plurality of connecting regions are defined on the upper surfaces;
a ring-shaped tape disposed on the upper surface of the inner leads, wherein the ringshaped tape has an opening leaving the connecting regions exposed;
a flip chip disposed on the upper surface of the inner leads, the flip chip having an active surface and a plurality of bumps formed thereon, the bumps being connected to the connecting regions of the inner leads; and
an underfilling material confined by the ring-shaped tape to be inside the opening for sealing the bumps.

2. The semiconductor package according to claim 1, wherein the leadframe comprises a heat spreader disposed underneath the flip chip, and flip chip comprises a heat conductive bump bonded onto the heat spreader.

3. The semiconductor package according to claim 1, wherein a material of the ring-shaped tape is polyimide or resin.
